(19) United States
(12) Patent Application Publication
(10) Pub. No.: US 2005/0137834 A1
(43) Pub. Date: Jun. 23, 2005

(54) System and method of estimating synchronous generator parameters

(76) Inventors: Gerald T. Heydt, Scottsdale, AZ (US); Elias Kyriakides, Nicosia (CY)

Correspondence Address: QUARLES & BRADY LLP, RENAISSANCE ONE, TWO NORTH CENTRAL AVENUE, PHOENIX, AZ, 85004-2391, US

(21) Appl. No.: 11/015,723

(22) Filed: Dec. 17, 2004

Related U.S. Application Data
(60) Provisional application No. 60/530,971, filed on Dec. 18, 2003.

(51) Int. Cl. H04B 15/00; G06F 15/00; H03F 1/26; G06F 17/10; G06F 7/60

(52) U.S. Cl. 702/189; 703/2

(57) ABSTRACT

A method of estimating parameters of an electric machine is disclosed. A known parameter of the electric machine is provided. A mathematical model representative of a physical characteristic of the electric machine is provided. The known parameter is utilized within the mathematical model to solve the mathematical model and obtain an estimation parameter. A graphical user interface (GUI) is used to perform parameter estimation. A parameter estimation system for electric machines coupled for receiving a known parameter is disclosed, which provides a mathematical model representative of a physical characteristic of a machine, utilizes the known parameter within the mathematical model to solve the mathematical model and obtain an estimation parameter. The system includes a GUI for implementation.

### CLAIM TO DOMESTIC PRIORITY

The present non-provisional patent application claims priority to provisional application Ser. No. 60/530,971 entitled “Algorithm for On-Line Synchronous Generator Parameter Estimation”, filed on Dec. 18, 2003, by Heydt et al.

### FIELD OF THE INVENTION

The present invention relates in general to electric machine performance estimators and, more particularly, to a system and method of estimating parameters of synchronous generators.

### BACKGROUND OF THE INVENTION

The problem of power system state estimation has attracted the attention of many researchers since the late 1960s. The researcher's main objective has been to develop a technique to monitor the power system and to calculate its system states by using other available data. Interest in identifying parameters in generators arose about a decade later. Knowledge of the operational parameters of generators is necessary for performing stability studies and post mortem analyses of failures.

Generator parameters are in general not constant throughout the useful life of a synchronous machine or generator. Some parameters, such as the magnetizing inductances in the direct and quadrature axes, vary at different operating points due to the effect of magnetic saturation. Magnetizing inductances and other parameters also change because of aging, since generator parameters are tied to properties of physical materials in the generator windings that undergo changes in their physical characteristics as generators age. Further, major changes in generator parameters occur after a repair. Rewinding of the rotor of a generator would cause the field resistance to be different than its originally designed value. For these reasons, parameter estimation is necessary to ensure that the parameters used in different power system studies are accurate, and that the interpretation of the results of such studies is correct.

Traditionally, synchronous generator parameters are obtained by manufacturer data sheets and verified and enhanced by off-line tests, as described in IEEE Standards. Several researchers between 1969 and 1971 developed methods to find additional parameter values based on classical synchronous machine models. Off-line methods, however, are neither practical nor accurate in most cases. Decommiting a generator for parameter measuring is not economical for a utility, especially if the specific generator is a base loaded unit.

Contrary to off-line methods, an on-line method to identify generator parameters is very attractive to utilities because of its minimal interference in the normal operation of the generator. Ideally, generator parameters would be calculated under different operating conditions, both in steady-state and transient operation. In this way, an anomaly in a power system can be detected promptly. Remedial action or preventative measures could be taken so as to avoid costly outages. On-line methods can allow a utility company to satisfy a mandate of a regional coordinating council such as the North American Electric Reliability Council (NERC) to conduct periodic generator parameter tests in a more efficient manner.

Researchers have attempted to tackle the parameter estimation problem using various methods. One of these methods used an estimation of parameters from Standstill Frequency Response (SSFR) test data. Another method accomplished parameter identification using the recursive maximum likelihood technique. In addition, various estimation techniques have been proposed, which include least squares, infinite-norm and 1-norm estimation methods. These methods often require undesirable off-line measurements.

A need exists for an accurate model of synchronous generators that allows for on-line estimation of unknown parameters using recorded operating data. Estimation of synchronous generator model parameters is a fairly complex mathematical procedure, and there is a need for an easily used mechanism for model parameter estimation.

### SUMMARY OF THE INVENTION

In one embodiment, the present invention is a method for estimating parameters of an electric machine, comprising receiving a known analog parameter, converting the known analog parameter to a digital parameter, processing the digital parameter to obtain an estimation parameter by providing a mathematical model representative of a physical characteristic of the electric machine and utilizing the digital parameter within the mathematical model to solve the mathematical model and obtain the estimation parameter.

In another embodiment, the present invention is a method of estimating parameters of an electric machine, comprising providing a known parameter of the electric machine, providing a mathematical model representative of a physical characteristic of the electric machine, and utilizing the known parameter within the mathematical model to solve the mathematical model and obtain an estimation parameter.

In another embodiment, the present invention is a computer system for estimating parameters in an electric machine, comprising means for providing a known parameter of the electric machine, means for providing a mathematical model representative of a physical characteristic of the electric machine, and means for utilizing the known parameter within the mathematical model to solve the mathematical model and obtain an estimation parameter.

In another embodiment, the present invention is a computer program product usable with a programmable computer processor having a computer readable program code embodied therein, comprising computer readable program code which provides a known parameter of an electric machine, computer readable program code which provides a mathematical model representative of a physical characteristic of the electric machine and computer readable program code which utilizes the known parameter within the mathematical model to solve the mathematical model and obtain an estimation parameter.

### BRIEF DESCRIPTION OF THE DRAWINGS

FIG. 1 illustrates an exemplary system of estimating parameters of a synchronous generator;

FIG. 2 illustrates an exemplary process of an observer for estimating parameters of a synchronous generator;

FIG. 3 illustrates an exemplary noise filtering process;

FIG. 4a illustrates an exemplary process of implementing an observer and parameter identification method;

FIG. 4b illustrates an exemplary process of implementing an observer and parameter identification method;

FIG. 5 illustrates an exemplary process flow diagram of parameter estimation;

FIG. 6 illustrates an exemplary process flow diagram for implementing and executing a graphical user interface (GUI);

FIG. 7 illustrates an exemplary GUI input screen; and

FIG. 8 illustrates an exemplary GUI output screen.

### DETAILED DESCRIPTION OF THE DRAWINGS

The present invention is described in one or more embodiments in the following description with reference to the Figures, in which like numerals represent the same or similar elements. While the invention is described in terms of the best mode for achieving the invention's objectives, it will be appreciated by those skilled in the art that it is intended to cover alternatives, modifications, and equivalents as can be included within the spirit and scope of the invention as defined by the appended claims and their equivalents as supported by the following disclosure and drawings.

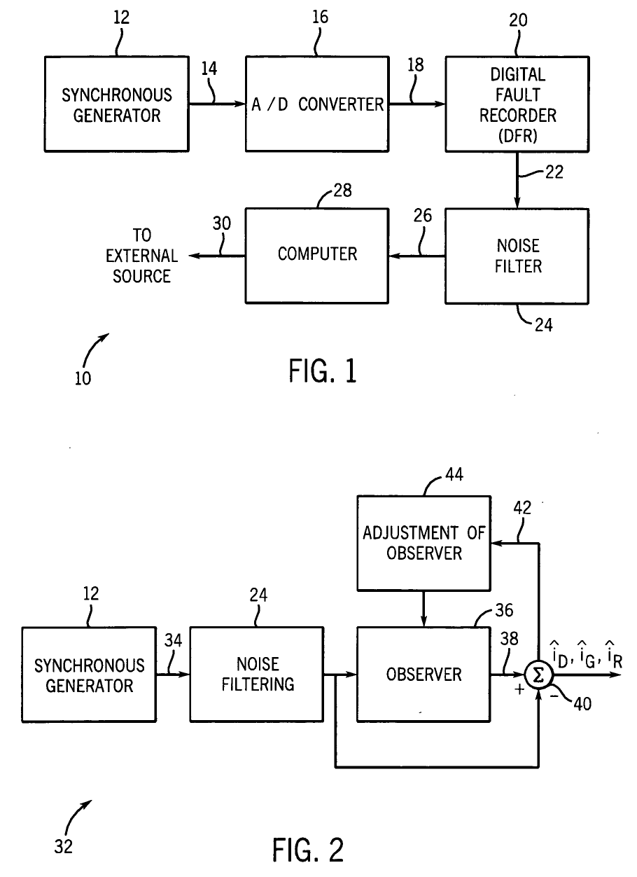

Turning to FIG. 1, an exemplary system of estimating parameters for a synchronous generator 10 is shown. System 10 contains the following major components which are connected by various system links: synchronous generator 12, analog-to-digital (A/D) converter 16, digital fault recorder (DFR) 20, noise filter 24, and computer 28.

Synchronous generator 12 includes a stationary structure referred to as a stator that has associated windings. Generator 12 has three stator windings that are 120 electrical degrees apart. Generator 12 also includes a rotating structure commonly referred to as a rotor. The rotor also has associated windings. In one example, generator 12 has three stator windings, one for each associated electrical phase. Generator 12 has an associated winding or windings in its rotor, which can include field or damper windings.

Measurements of the currents and voltages in the three stator windings and the field winding are usually available. Measurements can be directly obtained from generator 12 itself. A voltage from a phase of the stator can be measured by a voltmeter connected between a terminal located on generator 12 and ground. In contrast, the damper currents in a synchronous generator are not possible to be measured.

Link 14 represents the physical measurements which are obtained from generator 12. Physical measurements are passed through link 14 into a respective A/D converter 16 which converts the information from an analog form to a digital form.

Once voltage and current measurements are converted to digital form, the voltage and current measurements are passed through link 18 to a digital fault recorder (DFR) 20 where the voltage and current measurements are recorded. A DFR is effectively a data acquisition system that is used to monitor the performance of generation and transmission equipment, and therefore is connected permanently to utility generators. DFR 20 is typically used by the majority of electrical utilities to monitor the operation of generators. In one example, DFR 20 records a measurement 86 times per cycle, translating to roughly 5160 measurements being taken and recorded per second, or a frequency equivalent of 5 kHz. Other sampling rates may be utilized. The data files are typically of the COMTRADE data file format, which is an approved IEEE data format for storage of measurements. The data can either be in ASCII format or binary format.

Once measurements are recorded by DFR 20, measurements can be forwarded through link 22 to a noise filter 24. The specific purpose and function of noise filter 24 will be discussed below. For introductory purposes, however, it can be assumed that noise filter 24 helps to pre-process the digital measurement data.

Noise filter 24 can forward the filtered data through link 26 to computer 28. In addition, noise filter 24 can be located on computer 28. Computer 28 can have an associated microprocessor, hard disk or mass storage device, memory, and an associated communication port. Computer 28 with associated sub-components takes incoming measurement data and further processes the data. A method of parameter estimation can take place through the use of a computer program product located on computer 28. Computer 28 can be used to perform the calculations and estimations related to the method discussed below. Computer 28 can take processed measurement data and estimated parameters and forward the data through an onboard communication port through link 30 to an external source. Computer 28 can be a computer system which accomplishes parameter estimation.

To accomplish estimation of unknown generator parameters, it is necessary to generate and use a mathematical model of generator 12 to symbolically represent the physical characteristics of generator 12. The need to numerically solve differential equations is part of the mathematical model. The generated model can involve differential equations, which have to be solved iteratively for data generation and program testing. The truncated Taylor series uses a p^{th} order derivative series to estimate the solution. The Euler series uses the first two terms of the Taylor series, resulting in a first order approximation that has an error of the order of the time step used. If the time step is small enough (the size depends on the application), the Euler method is a good approximation that can be easily implemented.

Multi-step methods are also available such as the midpoint method, the Milne's method and the Adams-Bashforth method. Multi-step methods, however, require more than one starting value and are hence difficult to implement. Other methods such as the trapezoidal and the parabolic methods can also be used.

One example model A has three stator windings which are 120 electrical degrees apart and one rotor structure that is composed of two imaginary axes: the direct axis and the quadrature axis. The direct axis (d axis) has one field winding and one damper winding. The quadrature axis (q axis) has two damper windings. The two damper windings on the q axis assist in obtaining a symmetric model with respect to the two imaginary axes and are particularly useful in the correct representation of round rotor synchronous generator 12.

Using example model A further, the seven windings mentioned above (three in the stator and four in the rotor) are magnetically coupled. The coupling is a function of the rotor position. As a result, the flux linking each winding is also a function of the rotor function. The instantaneous terminal voltage of any winding in example model A takes the form,
v=−ri−λ′, (1)
where r is the winding resistance, i is the current, and λ is the flux linkage. The prime symbol (′) denotes a derivative with respect to time. It should be noted that in the notation described in equation (1), it is assumed that the direction of positive stator currents is out of the terminals, since the synchronous machine under consideration is a generator.

In the late 1920s, Park formulated a change of variables which replaced the variables associated with the stator windings of synchronous machines with variables associated with fictitious windings that are rotating with the rotor. The direction of rotation and the alignment of the d axis and q axis are defined in agreement with IEC Standard 34-10 and IEEE Standard 100-1984.

Park's transformation eliminates the time-varying inductances from voltage equations associated with example model A. Park's transformation is useful in helping to mathematically model a synchronous generator. As a result, it is useful to apply the transformation to example model A.

In Park's transformation, the d axis of the rotor is defined to be at an angle Θ radians with respect to a fixed reference position at some instant of time. If the stator phase currents iₐ, i_{b}, and i_{c} are projected along the d and q axes of the rotor, the following relationships are obtained,
i_{q}=(2/3)×[iₐ sin Θ+i_{b} sin(Θ−2π/3)+_{c} sin(Θ+2π/3)]
i_{d}=(2/3)×[iₐ cos Θ+i_{b} cos(Θ−2π/3)+i_{c} cos(Θ+2π/3)]. (2)

The effect of the above transformation is to convert the stator quantities from phases a, b, and c to new variables, the frame of which moves with the rotor. However, since there are three variables in the stator, it is necessary to have three variables in the rotor for balance. The third variable is on a third axis: the stationary axis. The third variable is a stationary current proportional to the zero-sequence current. The third variable is zero under balanced conditions. Therefore, from equation (2), a matrix P called Park's transformation can be defined, such that,
i_{0dq}=Pi_{abc,} (3)
where the current vectors are defined as,

$${i}_{0 dq} = [ \begin{matrix}{i}_{0} \\ {i}_{d} \\ {i}_{q}\end{matrix} ] and {i}_{abc} = [ \begin{matrix}{i}_{a} \\ {i}_{b} \\ {i}_{c}\end{matrix} ] . \qquad ( 4 )$$

The Park's transformation is thus defined as,

$$P = \sqrt{\frac{2}{3}} [ \begin{matrix}1 / \sqrt{2} & 1 / \sqrt{2} & 1 / \sqrt{2} \\ cos ϑ & cos ( ϑ - 2 π / 3 ) & cos ( ϑ + 2 π / 3 ) \\ sin ϑ & sin ( ϑ - 2 π / 3 ) & sin ( ϑ + 2 π / 3 )\end{matrix} ] . \qquad ( 5 )$$

In order to perform Park's transformation, it is necessary to calculate the angle Θ. The flux of the main field winding is along the direction of the d axis of the rotor. The flux produces an electro-motive force (EMF) that is lagging by 90°. Therefore, the machine EMF E is mainly along the q axis of the rotor. If a machine with terminal voltage V is considered, the phasor E should lead the phasor V if the machine is to be operated as a generator. The angle between E and V is denoted as the machine torque angle δ if V is in the direction of phase a (reference phase).

Park's transformation can also be used to convert voltages and flux linkages from abc quantities to 0dq quantities. The expressions are identical to the expressions for the current and are given by,
v_{0dq}=Pv_{abc} and λ_{0dq}=Pλ_{abc.} (6)

Equation (1) in its expanded form becomes,

$$\begin{matrix}[ \begin{matrix}{v}_{a} \\ {v}_{b} \\ {v}_{c} \\ - {v}_{F} \\ - {v}_{D} \\ - {v}_{G} \\ - {v}_{Q}\end{matrix} ] = - [ \begin{matrix}{r}_{a} & 0 & 0 & 0 & 0 & 0 & 0 \\ 0 & {r}_{b} & 0 & 0 & 0 & 0 & 0 \\ 0 & 0 & {r}_{c} & 0 & 0 & 0 & 0 \\ 0 & 0 & 0 & {r}_{F} & 0 & 0 & 0 \\ 0 & 0 & 0 & 0 & {r}_{D} & 0 & 0 \\ 0 & 0 & 0 & 0 & 0 & {r}_{G} & 0 \\ 0 & 0 & 0 & 0 & 0 & 0 & {r}_{Q}\end{matrix} ] \\ [ \begin{matrix}{i}_{a} \\ {i}_{b} \\ {i}_{c} \\ {i}_{F} \\ {i}_{D} \\ {i}_{G} \\ {i}_{Q}\end{matrix} ] - [ \begin{matrix}{\dot{λ}}_{a} \\ {\dot{λ}}_{b} \\ {\dot{λ}}_{c} \\ {\dot{λ}}_{F} \\ {\dot{λ}}_{D} \\ {\dot{λ}}_{G} \\ {\dot{λ}}_{Q}\end{matrix} ] + [ \begin{matrix}{v}_{n} \\ 0\end{matrix} ] .\end{matrix} \qquad ( 7 )$$

Equation (7) is transformed into a 0dq frame of reference through a Park's transformation according to equations (3) and (6). The system of equations is converted into the system's per unit form and the following relations are used to simplify the model.
L_{d}=L_{AD}+l_{d} L_{q}=L_{AD}+l_{q}
L_{F}=L_{AD}+l_{F} L_{G}=L_{AD}+l_{G}
L_{D}=L_{AD}+l_{D} L_{Q}=L_{AD}+l_{Q}
kM_{F}=kM_{D}=M_{X}=L_{AD}
kM_{G}=kM_{Q}=M_{Y}=L_{AQ} (8)

The resulting synchronous generator model that is used for the parameter estimation is thus given by,

$$[ \begin{matrix}{v}_{0} \\ {v}_{d} \\ {v}_{q} \\ - {v}_{F} \\ - {v}_{D} \\ - {v}_{G} \\ - {v}_{Q}\end{matrix} ] = - [ \begin{matrix}r + 3 {r}_{n} & 0 & 0 & 0 & 0 & 0 & 0 \\ 0 & r & ω ( {L}_{AQ} + {l}_{q} ) & 0 & 0 & ω {L}_{AQ} & ω {L}_{AQ} \\ 0 & - ω ( {L}_{AD} + {l}_{d} ) & r & - ω {L}_{AD} & - ω {L}_{AD} & 0 & 0 \\ 0 & 0 & 0 & {r}_{F} & 0 & 0 & 0 \\ 0 & 0 & 0 & 0 & {r}_{D} & 0 & 0 \\ 0 & 0 & 0 & 0 & 0 & {r}_{G} & 0 \\ 0 & 0 & 0 & 0 & 0 & 0 & {r}_{Q}\end{matrix} ] [ \begin{matrix}{i}_{0} \\ {i}_{d} \\ {i}_{q} \\ {i}_{F} \\ {i}_{D} \\ {i}_{G} \\ {i}_{Q}\end{matrix} ] - \frac{1}{{ω}_{B}} \cdot [ \begin{matrix}{L}_{0} + 3 {L}_{n} & 0 & 0 & 0 & 0 & 0 & 0 \\ 0 & {L}_{AD} + {l}_{d} & 0 & {L}_{AD} & {L}_{AD} & 0 & 0 \\ 0 & 0 & {L}_{AQ} + {l}_{q} & 0 & 0 & {L}_{AQ} & {L}_{AQ} \\ 0 & {L}_{AD} & 0 & {L}_{AD} + {l}_{F} & {L}_{AD} & 0 & 0 \\ 0 & {L}_{AD} & 0 & {L}_{AD} & {L}_{AD} + {l}_{D} & 0 & 0 \\ 0 & 0 & {L}_{AQ} & 0 & 0 & {L}_{AQ} + {l}_{G} & {L}_{AQ} \\ 0 & 0 & {L}_{AQ} & 0 & 0 & {L}_{AQ} & {L}_{AQ} + {l}_{Q}\end{matrix} ] [ \begin{matrix}{\dot{i}}_{0} \\ {\dot{i}}_{d} \\ {\dot{i}}_{q} \\ {\dot{i}}_{F} \\ {i}_{D} \\ {\dot{i}}_{G} \\ {\dot{i}}_{Q}\end{matrix} ] \qquad ( 9 )$$

where all quantities are in per unit except ω_{B} which is in rad/s and time which appears in the derivative terms in seconds.

All parameters in the coefficient matrices are constant. Furthermore, since the rotor speed is nearly constant if small time periods are studied, equation (9) can be considered as a linear time invariant differential equation.

Damper (amortisseur) windings form one of the factors for damping in power systems. The action of damper windings is relevant to the operation of electrical generators and to the stability of the power system as a whole.

In the case of salient pole generators, damper windings consist of metal bars placed in slots in the pole faces and connected together at each end. The metal bars can be connected together via a closed ring on both sides of the pole. In this case, the windings are called complete or connected damper windings. It is also possible for the bars not to be connected in between the poles, but for each pole to have its own independent set of metal bars. In this case, the damper windings are known as incomplete, non-connected, or open windings.

In the case of round-rotor generators (steam and gas turbines), the rotors are made up of solid steel forgings. Round-rotor generators do not usually have damper windings, but the solid steel rotor core provides a path for eddy currents. The eddy currents in the rotor path produce the same effect as damper windings. In some cases, certain manufacturers provide for additional damping effects and negative sequence braking by using interconnected metal wedges in the field winding slots or by providing separate metal rods underneath the wedges.

There are several reasons for providing damper windings for synchronous machines. Damper windings provide starting torque for synchronous motors, condensers, and converters. Damper windings are used to suppress hunting, which is the damped mechanical oscillation of the rotor about the rotor's new steady state angle after the mechanical speed of the rotor has changed.

Further, damper windings are used to damp oscillations that are started by switching or faults. The existence of damper windings causes the oscillations to damp out faster. In the case of asymmetrical faults, the damper currents provide a braking torque and therefore the accelerating torque is reduced during the fault. Another application of damper windings is the balancing of the terminal voltage of each phase during unbalanced loading. Damper windings decrease the negative sequence reactance and therefore damper windings decrease the negative sequence voltage.

During current surges in the armature circuit (in case of internal faults), the damper windings reduce the stress on the insulation of the field winding by the induced flux through the windings. Finally, the damper windings provide additional torque for synchronizing generators. Damper windings help to pull the generator back into step after synchronism is lost because of a fault.

In the case of the voltages in equation (9), all damper winding voltages v_{D}, v_{G}, and v_{Q} are zero since there is no voltage source in the damper windings. In the case of a doubly excited synchronous generator the model of equation (9) can still describe the synchronous machine but v_{G} will not be zero. Damper currents are zero (or very small) in the steady state operation of the synchronous generator, and nonzero during transients. However, it is not possible to measure the damper currents directly using physical instruments, even in the case that the damper windings are not fictitious. Therefore, it is necessary to estimate the damper currents by means of an observer prior to the implementation of a state estimator for the generator parameters.

The general concept of an observer is as follows: certain states of a physical system can be difficult to measure or calculate. These unobserved states can nonetheless be needed to calculate an estimate of the machine parameters. An ‘observer’ is a dynamic system that is constructed so that the unobserved states can be estimated. The observer is adaptive: parameters of the observer are adjusted methodically so that the output of the machine simulation agrees with the actual measured machine output.

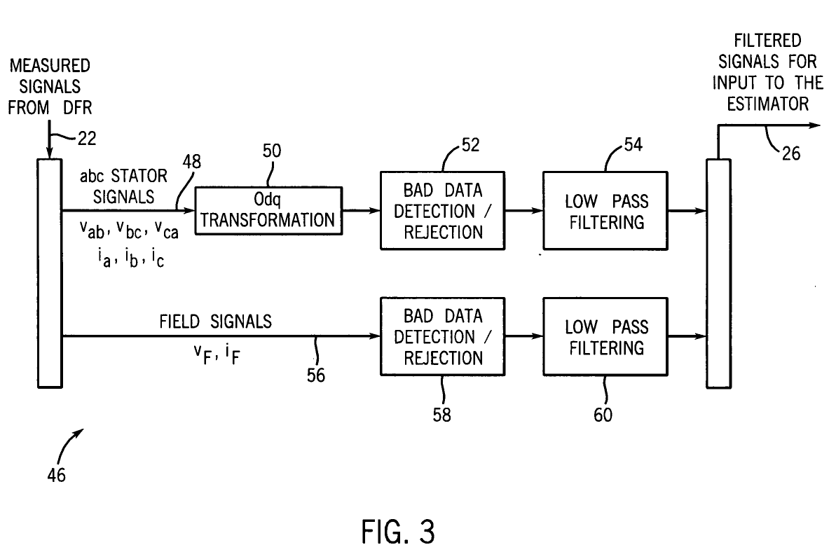

Turning to FIG. 2, an exemplary process of an observer 32 is shown in block diagram format. Synchronous generator 12 is seen providing measured parameters though link 34 to noise filter 24 where the measured parameters undergo noise filtering. Once pre-processing is completed, the measured parameters are forwarded to observer 36. Observer 36 can include measured parameters which are forwarded from noise filter 26. Observer 36 can include manufacturer-provided parameter information that has been calculated at the time of manufacture. Manufacturer information can serve as a baseline for additional decision making or error analysis. Observer 36 can include means to operate a simulation of the machine or generator to provide simulated output parameter data.

Observer 36 is seen providing processed information through link 38 to a summing module 40. Summing module 40 takes information received through link 38 from observer 36, and receives original data directly from noise filter 24. Summing module 40 compares observer-provided parameter data with measured data received from noise filter 24. The difference can be forwarded for error calculation. The error between estimated and simulated currents can be calculated using the formula

$$\% error = \frac{{‖ {i}_{simulated} - {i}_{observed} ‖}_{2}}{{‖ {i}_{simulated} ‖}_{2}} \times 100 ,$$

where ∥.∥₂ denotes the 2-norm (square root of the sum of the squares of all the elements).

The result obtained from summing module 40 is forwarded through link 42 to where a decision as to how to adjust the observer is made, shown here as adjustment module 44. Adjustment module 44 receives result information from summing module 40. Based on the results received, adjustment module 44 can decide to adjust certain parameters so that the output of a machine simulation agrees with actual measured parameters of the system. Observer 36 and related components can operate by means of a computer program product executing on computer 28.

For the construction of the observer, the last three equations of the synchronous generator model in equation (9) can be rearranged so as to obtain expressions for the damper winding currents. The three equations are given by,

$$\begin{matrix}\begin{matrix}- {v}_{D} = 0 \\ = - {r}_{D} {i}_{D} - \frac{1}{{ω}_{B}} {L}_{AD} {i}_{d}^{′} - \frac{1}{{ω}_{B}} {L}_{AD} {i}_{F}^{′} - \frac{1}{{ω}_{B}} ( {L}_{AD} + {l}_{D} ) {i}_{D}^{′}\end{matrix} & ( 10 ) \\ \begin{matrix}- {v}_{G} = 0 \\ = - {r}_{G} {i}_{G} - \frac{1}{{ω}_{B}} {L}_{AQ} {i}_{q}^{′} - \frac{1}{{ω}_{B}} ( {L}_{AQ} + {l}_{G} ) {i}_{G}^{′} - \frac{1}{{ω}_{B}} {L}_{AQ} {i}_{Q}^{′}\end{matrix} & ( 11 ) \\ \begin{matrix}- {v}_{Q} = 0 \\ = - {r}_{Q} {i}_{Q} - \frac{1}{{ω}_{B}} {L}_{AQ} {i}_{q}^{′} - \frac{1}{{ω}_{B}} {L}_{AQ} {i}_{G}^{′} - \frac{1}{{ω}_{B}} ( {L}_{AQ} + {l}_{Q} ) {i}_{Q}^{′}\end{matrix} & ( 12 )\end{matrix}$$

where for the purposes of the development of the observer the current derivatives are replaced by the forward difference formula,

$${i}^{′} ( t ) \approx \frac{i ( t + Δ t ) - i ( t )}{Δ t} . \qquad ( 13 )$$

Other numerical differentiation formulas for the above calculation can be used. Solving equation (10) for i_{D}, an expression can be obtained in terms of known measurements and the value of i_{D} at the previous step.

$$\begin{matrix}{i}_{D} ( n + 1 ) = ( 1 - \frac{{r}_{D} {ω}_{B} Δ t}{{L}_{AD} + {l}_{D}} ) {i}_{D} ( n ) - \\ \frac{{L}_{AD} Δ t}{{L}_{AD} + {l}_{D}} ( {i}_{d}^{′} ( n ) + {i}_{F}^{′} ( n ) )\end{matrix} \qquad ( 14 )$$

The quadrature axis damper winding currents i_{G} and i_{Q} can be obtained by the simultaneous solution of equations (11) and (12) and are given by,

$$\begin{matrix}\begin{matrix}{i}_{G} ( n + 1 ) = [ 1 - \frac{( {L}_{AQ} + {l}_{Q} ) {r}_{G} {ω}_{B} Δ t}{( {L}_{AQ} + {l}_{Q} ) ( {L}_{AQ} + {l}_{G} ) - {L}_{AQ}^{2}} ] {i}_{G} ( n ) + \\ [ \frac{{L}_{AQ} {r}_{Q} {ω}_{B} Δ t}{( {L}_{AQ} + {l}_{Q} ) ( {L}_{AQ} + {l}_{G} ) - {L}_{AQ}^{2}} ] {i}_{Q} ( n ) + \\ [ \frac{{L}_{AQ} {l}_{G}}{( {L}_{AQ} + {l}_{Q} ) ( {L}_{AQ} + {l}_{G} ) - {L}_{AQ}^{2}} ] {i}_{q}^{′} ( n )\end{matrix} & ( 15 ) \\ \begin{matrix}{i}_{Q} ( n + 1 ) = [ 1 - \frac{( {L}_{AQ} + {l}_{G} ) {r}_{Q} {ω}_{B} Δ t}{( {L}_{AQ} + {l}_{Q} ) ( {L}_{AQ} + {l}_{G} ) - {L}_{AQ}^{2}} ] {i}_{Q} ( n ) + \\ [ \frac{{L}_{AQ} {r}_{G} {ω}_{B} Δ t}{( {L}_{AQ} + {l}_{Q} ) ( {L}_{AQ} + {l}_{G} ) - {L}_{AQ}^{2}} ] {i}_{G} ( n ) + \\ [ \frac{{L}_{AQ} {l}_{G} Δ t}{( {L}_{AQ} + {l}_{Q} ) ( {L}_{AQ} + {l}_{G} ) - {L}_{AQ}^{2}} ] {i}_{q}^{′} ( n )\end{matrix} & ( 16 )\end{matrix}$$

Equations (14-16) enable the calculation of the damper currents. All parameters can be accurately calculated using manufacturer's data, while the time varying quantities are available measurements. The only ambiguity in the observer equations is the value of i_{D}(0), i_{G}(0), and i_{Q}(0). These are needed to initiate the observation process. Nevertheless, the initial conditions can be assumed to be zero without loss of accuracy.

Real data have errors resulting mainly from meter and communication errors, incomplete metering, or inaccuracy of metering equipment. Therefore, prior to any estimation, it is expedient to perform bad data detection and rejection, and filtering of the noise. Noise filter 24 as shown in FIGS. 1 and 2 serves to perform the pre-processing function.

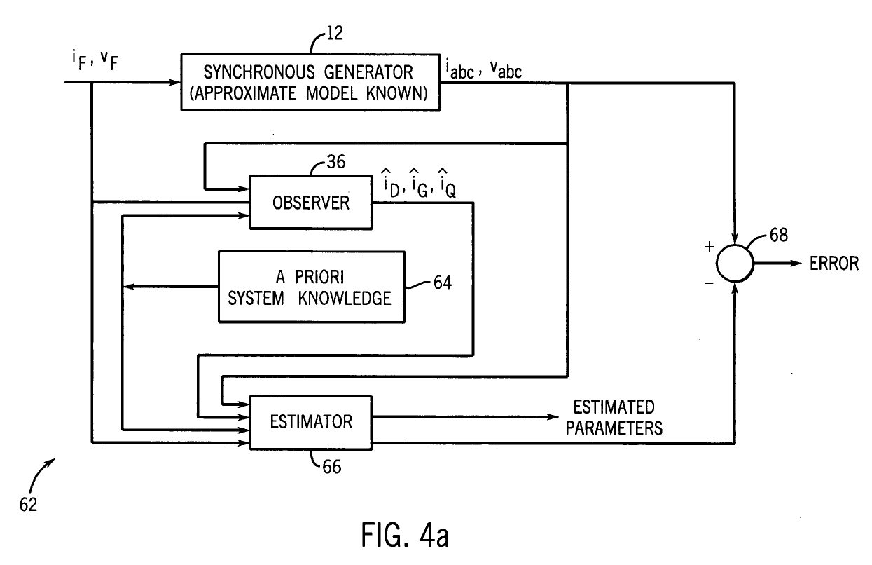

Turning to FIG. 3, an exemplary block diagram of a filtering and bad data detection/rejection process 46 is depicted. Measured signals from DFR 20 are shown entering into the filtering process through link 22. As a first step, voltage and current signals received from the stator in generator 12 are routed to a first data set 48. Field voltages and currents are separated into a second data set 56.

First data stream 48 takes stator measurements through a Park's transformation process 50. In the synchronous machine parameter estimation application, it is found that the stator measurements are most effectively filtered after the 0dq transformation. After the transformation of the stator measurements through Park's transformation, a filter is applied to remove outliers from the measurements, taking place in bad data detection/rejection process 52. Outliers appear in the form of spikes, in the time domain plot of each signal. Outliers are caused generally by metering errors and can be safely removed without risking inaccuracies in the estimation process. If a spike in any one signal is detected, the whole measurement at that time is removed from the data set.

Following process 52, a second, low pass filter process 54 is implemented for the removal of random noise. Finally, the filtered signals are collected and routed to an input in an estimator through link 26.

Field signals undergo a similar first bad data detection/rejection process 58 and second low pass filter process 60 before collection and routing to the estimator through link 26. Again, as before, filtering process 46 can be performed through a computer program product executing on computer 28, or filtering process 46 can exist separately as an external system. A combination of computer 28 and associated external filtering system with filtering process 46 can be present.

State estimation is a process that assigns values to a number of unknown system state variables based on measurements from the system. Typically, the number of measurements or number of equations is much greater than the number of parameters to be estimated, thus resulting in a mathematically overdetermined system.

As discussed above, the last three portions of equation (9) are used for the development of the observer. Now, in order to configure a state estimator, the remaining four portions of equation (9) are rearranged into the form Hx=z to obtain the estimated parameters by \hat{x}=H⁺z, where H⁺ is the pseudoinverse of H. Matrix H (the process matrix) is of dimension m×n and contains the coefficients of the unknowns, which are either obtained by direct measurements of current and voltages, or via the observer in the case of the damper currents, or via calculation in the case of the derivatives. The formula for the derivatives is the forward difference equation (13). The vector z has dimension m. The vector contains known parameters, or measurements or a combination of parameters and measurements.

If parameters L_{AD}, L_{AQ} and r_{F} are to be estimated, equation (9) can be rearranged in the form Hx=z to obtain,

$$[ \begin{matrix}0 & 0 & 0 \\ \frac{1}{{ω}_{B}} ( {i}_{d}^{′} + {i}_{F}^{′} + {i}_{D}^{′} ) & ω ( {i}_{q} + {i}_{G} + {i}_{Q} ) & 0 \\ - ω ( {i}_{d} + {i}_{F} + {i}_{D} ) & \frac{1}{{ω}_{B}} ( {i}_{q}^{′} + {i}_{G}^{′} + {i}_{Q}^{′} ) & 0 \\ \frac{1}{{ω}_{B}} ( {i}_{d}^{′} + {i}_{F}^{′} + {i}_{D}^{′} ) & 0 & {i}_{F}\end{matrix} ] [ \begin{matrix}{L}_{AD} \\ {L}_{AQ} \\ {r}_{F}\end{matrix} ] = - [ \begin{matrix}r + 3 {r}_{n} & 0 & 0 & 0 & 0 & 0 & 0 \\ 0 & r & ω {l}_{q} & 0 & 0 & 0 & 0 \\ 0 & - ω {l}_{d} & r & 0 & 0 & 0 & 0 \\ 0 & 0 & 0 & 0 & 0 & 0 & 0\end{matrix} ] [ \begin{matrix}{i}_{0} \\ {i}_{d} \\ {i}_{q} \\ {i}_{F} \\ {i}_{D} \\ {i}_{G} \\ {i}_{Q}\end{matrix} ] - \frac{1}{{ω}_{B}} \cdot [ \begin{matrix}{L}_{0} + 3 {L}_{n} & 0 & 0 & 0 & 0 & 0 & 0 \\ 0 & {l}_{d} & 0 & 0 & 0 & 0 & 0 \\ 0 & 0 & {l}_{q} & 0 & 0 & 0 & 0 \\ 0 & 0 & 0 & {l}_{F} & 0 & 0 & 0\end{matrix} ] [ \begin{matrix}{\dot{i}}_{0} \\ {\dot{i}}_{d} \\ {\dot{i}}_{q} \\ {\dot{i}}_{F} \\ {i}_{D} \\ {\dot{i}}_{G} \\ {\dot{i}}_{Q}\end{matrix} ] - [ \begin{matrix}{V}_{0} \\ {V}_{d} \\ {V}_{q} \\ - {V}_{F} \\ - {V}_{D} \\ - {V}_{G} \\ - {V}_{Q}\end{matrix} ] \qquad ( 17 )$$

In this way, the four unknown parameters and their coefficients are isolated on the left hand side, and all elements of the right hand side are known. Moreover, the right hand side reduces to a vector and therefore the system takes the final form Hx=z. It should be noted that equation (17) is constructed using data from a single time step. The resulting system will consist of a large number of equations identical to equation (17) to reflect every time step in the available measurements. If m measurements (data points) are obtained, the system will have 4 m equations.

The linear system Hx=z represents multiple time steps. Each measurement results in an equation of the form Hx=z. At each subsequent time step, the new data are augmented to the existing H matrix and z vector to create an overdetermined system.

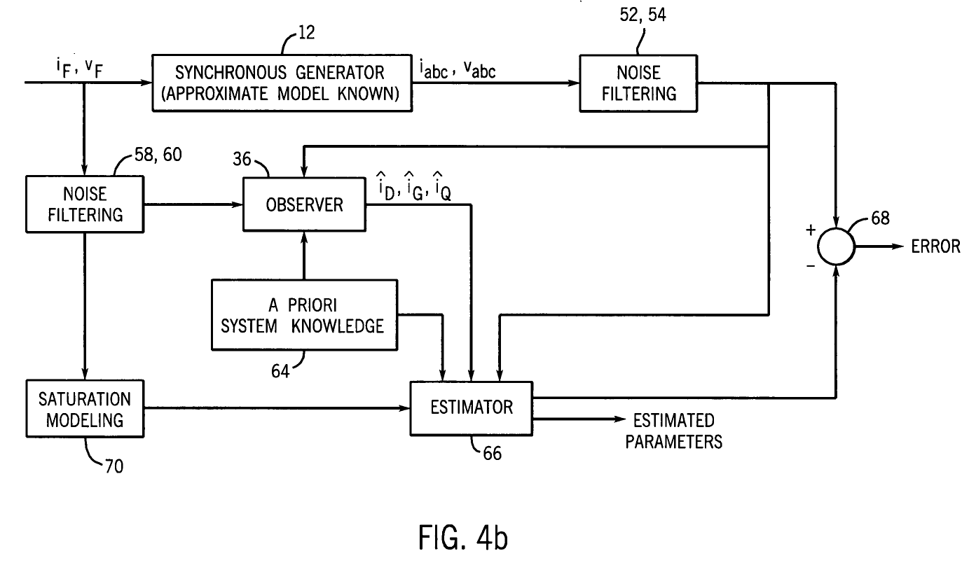

Turning to FIG. 4a, an exemplary block diagram for implementing an observer and a parameter identification method 62 is depicted. Field currents and field voltages, here denoted as i_{F} and v_{F}, are seen entering generator 12. The voltages and currents are supplied to the field windings on generator 12, and hence, can be measured as the voltages and currents are applied.

Stator voltage and current measurement data, here denoted as i_{abc} and v_{abc}, are seen leaving generator 12. Stator voltage and current information is fed, along with field voltage and current information, as well as a priori system information, to observer 36 for damper current estimation as previously described. Observer 36 outputs estimated damper current information to an estimator 66 where parameter estimation takes place. To accomplish parameter estimation, estimator 66 also receives measured field voltages and currents as well as measured stator voltages and currents. A priori system information plays a role. The input of known manufacturer data into estimator 66 serves as baseline data.

Estimator 66 performs parameter estimation calculations. Estimator 66 forwards processed data to an external source for further analysis. Estimator 66 provides data to a summing module 68, which receives measured parameter information as well as estimated parameter information. Summing module 68 uses the error process previously described to make an error calculation. The calculation or result is also forwarded to an external source for further analysis. Here, as before, method 62 takes place in the form of a computer program product executing on computer 28.

Turning to FIG. 4b, an exemplary block diagram for implementing an observer and a parameter identification method 63 is depicted. The depicted diagram includes the processes described in FIG. 4a. Generator 12, observer 36, a priori system information 64, estimator 66 and summing module 68 are again shown.

In addition to the previously described processes, FIG. 4b includes the processes of noise filtering as previously described by bad data detection/rejection process 52, low pass filtering process 54, bad data detection/rejection process 58 and low pass filtering process 60. Processes 52 and 54 serve to filter the measured stator currents and voltages measured from a terminal on generator 12 before the measured currents and voltages are passed to observer 36 or sent to summing module 68. Similarly, processes 58 and 60 serve to filter the measured field voltages and currents measured as the measured field voltages and currents are passed to generator 12 before the measured field voltages and currents are passed to observer 36 or routed to estimator 66.

Saturation modeling module 70 represents the optional inclusion of magnetic saturation into the method, which is performed between filtering processes 58, 60 and parameter estimation in estimator 66. Modeling of magnetic saturation will now be discussed.

The operating parameters of generators change according to the operating conditions of the machine. Change in parameters is mainly due to the magnetic saturation experienced by the generator inductances. Saturation is a phenomenon that becomes apparent when the current through an inductor exceeds a certain limit. In effect, saturation of an inductor occurs when the core of the inductor can no longer store magnetic energy.

Saturation representation is used in the correct modeling of synchronous machines. It is beneficial to model saturation so as to increase the reliability of the estimated parameters and benefit from such an estimation in improving the planning of synchronous machines.

The main effect of saturation in a synchronous generator is the decrease of its mutual inductances depending on the operating level of the generator. Such a decrease can be considerable as the generator is driven higher into saturation.

To illustrate the process of modeling magnetic saturation, example model B will be discussed. As a first step in constructing example model B, the effects of saturation for the mutual inductances L_{AD} and L_{AQ} can be represented by two saturation factors, one for each inductance. The saturated inductances are given by,
L_{ADs}=K_{sd}L_{ADu}
L_{AQs}=K_{sq}L_{AQu}, (18)
where K_{sd} and K_{sq} represent the saturation factors in each axis and the subscripts u and s refer to the unsaturated and saturated values of the inductance respectively. The two saturation factors represent the degree of saturation in the direct and quadrature axes. The saturation factors are in general not the same for both axes.

In the case of salient pole machines, K_{sq} is assumed to be unity for all loading conditions and thus L_{AQ} is considered a constant inductance. L_{AQ} is considered a constant inductance because the path for the quadrature axis flux is mainly in air and therefore the saturation experienced by L_{AQ} is insignificant. In the case of round rotor machines, saturation is significant in both the direct and quadrature axes. Both saturation factors need to be calculated from the d axis and q axis saturation curves. However, q axis saturation curves are typically not available and it is typically assumed that the q axis saturation factor is equal to the d axis saturation factor. The assumption of equal saturation factors effectively assumes that the reluctance of the magnetic path is homogeneous around the periphery of the rotor. The assumption of equal saturation effects also implies that the magnetic excitation in the direct and quadrature axes is equal.

The saturation factors K_{sd} and K_{sq} relate the degree of saturation in each axis to the available saturation characteristics (either supplied from the manufacturer, or estimated). An exponential saturation function of the form,

$${λ}_{1} = \{ \begin{matrix}0 , & {λ}_{at} \leq {λ}_{0} \\ {A}_{G} {ⅇ}^{{B}_{G} ( {λ}_{at} - {λ}_{0} )} , & {λ}_{at} > {λ}_{0} ,\end{matrix} \qquad ( 19 )$$

is defined in order to simulate the actual saturation curve and to enable the calculation of the saturation factors at any operating point. λ_{I} is the flux linkage component required to overcome the reluctance of the air gap and is an indication of the degree of saturation, λₐₜ is the open circuit terminal flux linkage at the operating condition, and λ₀ is the assumed saturation threshold, which can be obtained from the saturation curve (λ₀ is the per unit flux linkage at the point where the OCC deviates from the air-gap line). A_{G} and B_{G} are constants. The constants can be determined by the knowledge of at least two points on the saturation curve. To calculate A_{G} and B_{G} the value of the function at two flux linkages (or terminal voltages) needs to be calculated first. Typically the 1.0 p.u. and 1.2 p.u. points are selected for the calculation, and the values of λ_{I} are given by,

$${λ}_{I 1.0} = \frac{{I}_{B} - {I}_{A}}{{I}_{A}} and {λ}_{I 1 , 2} = \frac{{I}_{C} - 1.2 {I}_{A}}{1.2 {I}_{A}} . \qquad ( 20 )$$

Using equation (20) to solve for the constants A_{G} and B_{G}, it can be shown that,

$${A}_{G} = \frac{{λ}_{I 1.2}^{2}}{1.2 {λ}_{I 1.2}} and {B}_{G} = 5 ln ( \frac{1.2 {λ}_{I 1.2}}{{λ}_{I 1.0}} ) . \qquad ( 21 )$$

Using the values for A_{G}, B_{G}, and the saturation threshold λ₀, the saturation function λ_{I} can be calculated for any operating condition by calculating the terminal flux linkage λₐₜ. The terminal flux linkage λₐₜ is given by,
λₐₜ=\sqrt{λ_{ad}²+λ_{aq}²}, (22)
where,
λ_{ad}=λ_{d}+xₗi_{d}=v_{q}+ri_{q}+xₗi_{d}
λ_{aq}=λ_{q}+xₗi_{q}=−v_{d}−ri_{d}+xₗi_{q}. (23)
Alternatively,
λₐₜ=|Eₗ+(r+jxₗ)Iₗ|ᵣ (24)
where all quantities are in per unit.

The saturation factors for the direct and quadrature axes can be calculated as,

$${K}_{sd} = \frac{{λ}_{at}}{{λ}_{at} + {λ}_{ld}} and {K}_{sq} = \frac{{λ}_{at}}{{λ}_{at} + {λ}_{Iq}} , \qquad ( 25 )$$

where λ_{Id} and λ_{Iq} are calculated from equation (19) for the d and q axis respectively, using the open circuit characteristics for each axis if the characteristics are both available. If the q axis characteristic is neither available nor can be estimated, the saturation factor for the q axis can be assumed to be equal to the saturation factor for the d axis for a round rotor synchronous generator. The latter is the approach used in example model B, since the accurate determination of the q axis saturation factor is very involved and finite element based techniques are needed. Such a level of complexity is impractical in a conventional time domain program.

The calculation of the saturation is in general an iterative procedure because the power angle δ (used to calculate the 0dq currents and voltages) is usually not known and needs to be calculated using the q axis reactance x_{q}. However, the saturation factors converge after only one iteration. Further iterations produce no change in the saturation factors or the accuracy of the estimated parameters.

It should be noted that the approach selected to handle saturation is similar to the method employed in contemporary transient stability programs. In addition, other saturation models can be utilized in the same fashion as above to capture desired effects. Again, it should be noted that any mathematical modeling such as example model B could take place on computer 28. Such a model could be generated and implemented through a computer program product executing on computer 28.

To perform parameter estimation, as previously discussed, a number of steps are performed. These steps include the preprocessing of data into an acceptable format. Once the data is in the correct format, the step of actually implementing, calculating and executing the above mentioned state estimation algorithm must be accomplished.

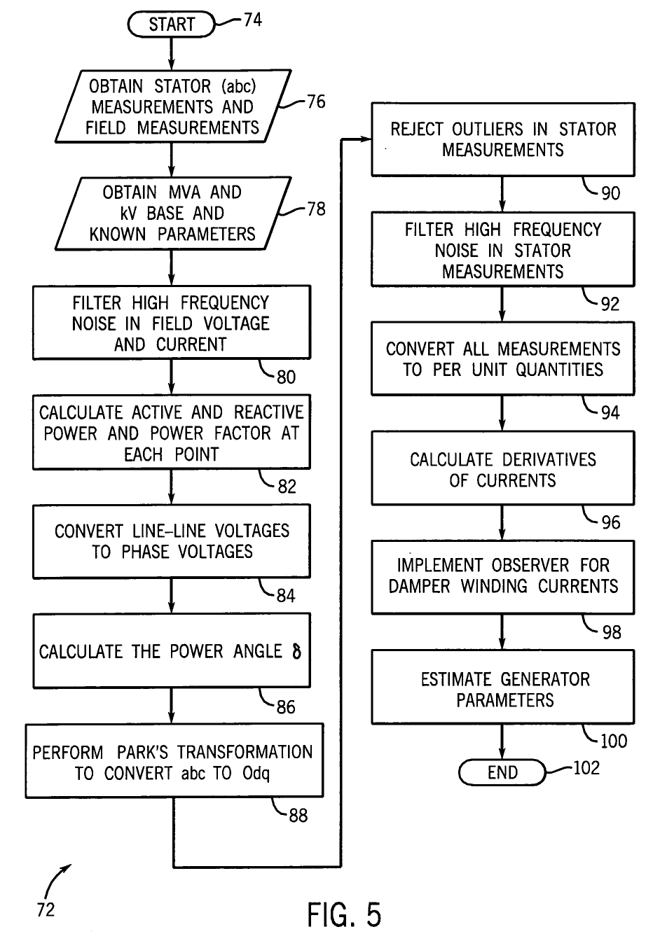

Turning to FIG. 5, an exemplary process flow diagram 72 of parameter estimation is depicted. Again, these processes can be accomplished through a computer program product executing on computer 28.

Start 74 begins the process. As a first step, process 72 obtains stator (abc) measurements and field measurements 76. Next, process 72 obtains manufacturer information, such as megavolt ampere (MVA) and/or kilovolt (KV) base information as well as other known parameters 78. Next, the data set is sent to a noise filter, where high frequency noise in the field voltage and field current is filtered 80.

As a next step, process 72 calculates active and reactive power, and the respective power factor 82. Line-to-line voltages are converted to phase voltages 84. The respective power angle is calculated 86. Next, process 72 performs a Park's transformation to convert stator measurements 88.

As a next step, process 72 rejects outliers in stator measurements 90, as accomplished through noise filter process 52. Next, a low pass filter process 54 filters high frequency noise in stator measurements 92. Next, all measurements are converted to per-unit quantities 94. Derivatives of currents are calculated 96. Process 72 can optionally implement an observer for damper winding currents 98. Optionally, and not shown, process 72 can implement a model for magnetic saturation. Finally, process 72 begins the process of execution of the parameter estimation algorithm, and estimates generator parameters 100. End 102 ends process 72.

Process 72 as depicted in FIG. 5 can utilize a graphical user interface (GUI) in the form of a Windows or similar application to assist in performing parameter estimation. In one example, a GUI allows a practicing engineer or interested utility to estimate the parameters of a synchronous generator without having to decommit the unit or get involved in time consuming off-line tests.

Again, as mentioned previously, on-line operation is a distinguishing characteristic of the previously mentioned process 72. Process 72 enables on-line and expeditious estimation of any given synchronous generator based on measurements of the field and stator voltages and currents. Such measurements are readily available and in large quantities in every electrical utility.

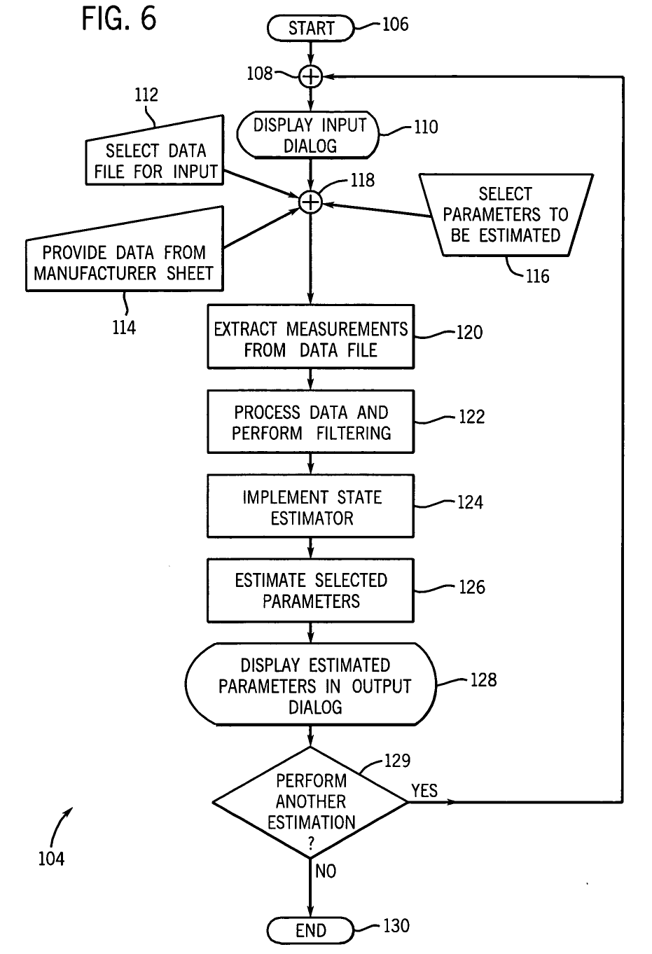

Turning to FIG. 6, an exemplary process flow diagram for implementing and executing a GUI 104 is depicted. Start 106 begins process 104. Decision node 108 accepts a decision from process 104 as to whether to initiate process 104 again once process 104 is completed. Process 104 next displays an input dialog 110. Depending on the user response, process 104, using decision node 118, either selects a data file for input 112, provides data from a manufacturer sheet 114, or selects parameters to be estimated 116.

As a next step, process 104 extracts measurements from a data file 120. The data file can be obtained from DFR 20. Next, process 104 processes the data and performs filtering 122. Next, process 104 implements a state estimator 124, which initializes a state estimation algorithm. Next, process 104 executes the respective state estimation algorithm to estimate selected parameters 126. As a next step, process 104 displays the estimated parameters in an output dialog 128. Upon display of the output dialog, process 104 decides whether to perform another estimation 129. If yes, process 104 returns to decision node 108 for further estimation. If no, end 130 ends process 104.

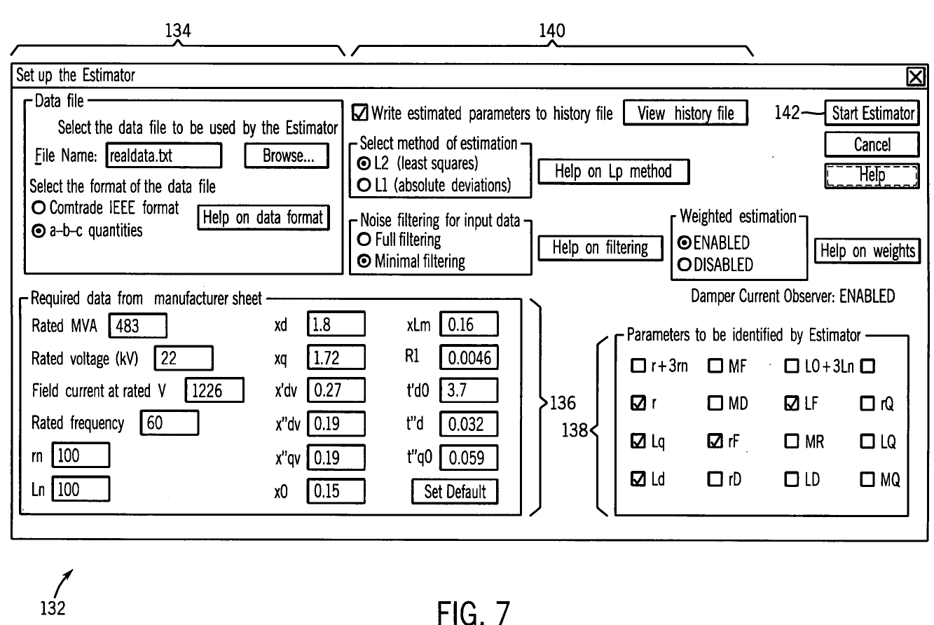

Turning to FIG. 7, an exemplary GUI input screen 132 of process 72 is depicted. As a preliminary matter, the main window of the GUI offers a variety of options on its toolbar, similar to any other Windows program. To illustrate the GUI and estimation method, exemplary user estimation example A will be discussed. As a first step in estimation example A, a user initiates the process of estimating generator parameters by first opening input screen 132. Initiating the process is achieved by selecting the option Estimator on the toolbar of the main window, and selecting the Setup Estimator option.

As can be seen in FIG. 7, input screen 132 is user-friendly. The user can set up the Estimator and calculate the parameters of the synchronous generator that is to be studied by following the directions on input screen 132. The first step is to enter the name of the data file in the edit box as shown in field 134. Entering the file can be done by clicking on the Browse button and navigating through the hard disk of computer 28 or any external drives until the desired file is located. The file can be of any data format type (.dat, .txt, etc.). If applicable, the user can select the IEEE COMTRADE option by clicking on the respective radio button and the Estimator will read the measurements as obtained directly from the measuring device that is connected to the generator. These files typically follow the IEEE COMTRADE Standard for power systems.

The second step in estimation example A is to input the required parameters as contained in the manufacturer data sheet of the synchronous generator. The user selects various options pertaining to the estimation process, as shown in field 136. It is possible to perform either a least squares estimation (L₂ minimization) or a minimization of absolute deviations using the L₁ norm, as shown in field 140.

Taking estimation example A further, the user selects the level of filtering that is desired, again as depicted in field 140. Of the two options, the full filtering is preferred since full filtering will minimize the noise content in the measured signals. The user is given the option to apply weights to the measurements. Applying weights is particularly useful if it is known that certain measurements are less reliable than other measurements. Further documentation on all the options is provided through context-sensitive help or through the buttons that are located on the input window, again as depicted in field 140.

The final step of configuring input screen 140 in example A is to select the parameters that need to be estimated, as depicted in field 138. The user has the opportunity to select up to five parameters for estimation. A selection can be performed by simply clicking on the check box corresponding to the parameter to be estimated, again as shown in field 138.

After completing the steps mentioned in the previous section, the user clicks the Start Estimator button 142 to enable estimation of the parameters. No other interaction is required from the user. The Estimator is responsible to read the data from the input file, perform the bad data detection and rejection algorithms, filter the noise from the measurements, and calculate the current derivatives as described. The Estimator implements the state estimation algorithm and returns the values of the estimated parameters as an output. Such processes have been previously discussed as processes 72 and 104.

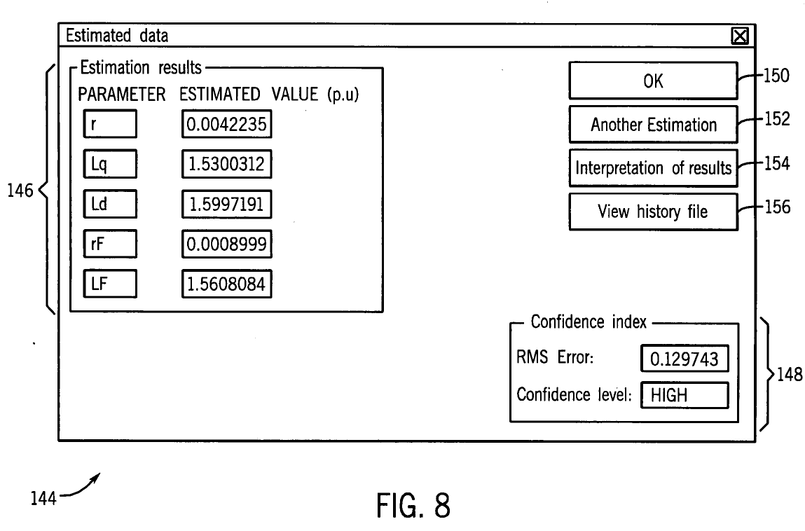

Returning to estimation example A, upon execution of the main program of the application the values of the estimated parameters, the rms error, and the confidence level in the estimated parameters are returned to the graphic user interface for output. The resulting output window 144 can be seen in FIG. 8. On the left side of the output window, as depicted in field 146, the user views the parameters that he/she previously selected and the parameters' estimated value in per unit. The root mean squared (rms) error on the lower right side of the estimator, as shown in field 148, is a measure of confidence on the estimated parameters and is given by,
rms error=\sqrt{residual/# of measurements}, (26)
where,
(residual)²={Hx−z}^{T}·{Hx−z}, (27)
and \hat{x} is the vector of the estimated parameters.

As a next step in estimation example A, a confidence level is offered to the user, again as shown in field 148. The confidence level has three states: high, average, or low. In this fashion, the user can verify whether the measurements used are reliable or not. A confidence level can be derived through the χ² test.

Small values of rms error as calculated by the Estimator indicate high reliability of results. Larger values of rms error indicate results that cannot be trusted for correct interpretation. The residual, which is the basis for the calculation of the rms error, is ideally equal to zero for error free estimations. The residual's value represents a measure of how closely the estimated values follow the measured or expected values. Instead of relying on intuition as to how large or how small the residual or the rms error should be, a standardized method could be followed to ascertain reliability of the results. A widely used method for such purposes is the χ² test, as previously mentioned.

The methods and processes previously discussed have been detailed with the primary objective of estimation of synchronous generator parameters. However, these methods can be utilized to estimate parameters for other machines, such as a synchronous machine that is operating as an electric motor. To estimate parameters in this situation, the underlying mathematical model of the machine is changed to reflect its physical characteristics. In large measure, the remaining processes would stay unchanged.

While one or more embodiments of the present invention have been illustrated in detail, the skilled artisan will appreciate that modifications and adaptations to those embodiments can be made without departing from the scope of the present invention as set forth in the following claims.

1. A method for estimating parameters of an electric machine, comprising:
receiving a known analog parameter;
converting the known analog parameter to a digital parameter;
processing the digital parameter to obtain an estimation parameter, by:
(a) providing a mathematical model representative of a physical characteristic of the electric machine, and
(b) utilizing the digital parameter within the mathematical model to solve the mathematical model and obtain the estimation parameter.

2. The method of claim 1, further including displaying the estimation parameter using a graphical user interface (GUI).

3. The method of claim 1, further including filtering the digital parameter to preprocess the digital parameter.

4. The method of claim 1, further including:
analyzing the known parameter of the electric machine to generate a first estimated parameter;
comparing the known parameter to the first estimated parameter to obtain a second estimated parameter; and
utilizing the second estimated parameter in the solution of the mathematical model.

5. The method of claim 1, further including calculating a magnetic saturation factor to provide an estimated parameter to the mathematical model.

6. A method of estimating parameters of an electric machine, comprising:
providing a known parameter of the electric machine;
providing a mathematical model representative of a physical characteristic of the electric machine; and
utilizing the known parameter within the mathematical model to solve the mathematical model and obtain an estimation parameter.

7. The method of claim 6, further including displaying the estimation parameter using a graphical user interface (GUI).

8. The method of claim 6, further including filtering the known parameter of the electric machine to preprocess the known parameter.

9. The method of claim 6, further including:
analyzing the known parameter of the electric machine to generate a first estimated parameter;
comparing the known parameter to the first estimated parameter to obtain a second estimated parameter; and
utilizing the second estimated parameter in the solution of the mathematical model.

10. The method of claim 6, further including calculating a magnetic saturation factor to provide an estimated parameter to the mathematical model.

11. A computer system for estimating parameters in an electric machine, comprising:
means for providing a known parameter of the electric machine;
means for providing a mathematical model representative of a physical characteristic of the electric machine; and
means for utilizing the known parameter within the mathematical model to solve the mathematical model and obtain an estimation parameter.

12. The method of claim 11, further including means for displaying the estimation parameter using a graphical user interface (GUI).

13. The method of claim 11, further including means for filtering the known parameter of the electric machine to preprocess the known parameter.

14. The computer system of claim 11, further including:
means for analyzing the known parameter of the electric machine to generate a first estimated parameter;
means for comparing the known parameter to the first estimated parameter to obtain a second estimated parameter; and
means for utilizing the second estimated parameter in the solution of the mathematical model.

15. The computer system of claim 11, further including means for calculating a magnetic saturation factor to provide an estimated parameter to the mathematical model.

16. A computer program product usable with a programmable computer processor having a computer readable program code embodied therein, comprising:
computer readable program code which provides a known parameter of an electric machine;
computer readable program code which provides a mathematical model representative of a physical characteristic of the electric machine; and
computer readable program code which utilizes the known parameter within the mathematical model to solve the mathematical model and obtain an estimation parameter.

17. The computer program product of claim 16, further including computer readable program code which displays the estimation parameter using a graphical user interface (GUI).

18. The computer program product of claim 16, further including computer readable program code which filters the known parameter to preprocess the known parameter.

19. The computer program product of claim 16, further including computer readable program code which:
analyzes the known parameter of the electric machine to generate a first estimated parameter;
compares the known parameter to the first estimated parameter to obtain a second estimated parameter; and
utilizes the second estimated parameter in the solution of the mathematical model.

20. The computer program product of claim 16, further including computer readable program code which calculates a magnetic saturation factor to provide an estimated parameter to the mathematical model.
